(19) United States
(12) Patent Application Publication
(10) Pub. No.: US 2023/0402572 A1
(43) Pub. Date: Dec. 14, 2023

(54) LIGHT-EMITTING DEVICE

(71) Applicant: TIANJIN SANAN OPTOELECTRONICS CO., LTD., Tianjin (CN)

(72) Inventors: Yuehua JIA, Tianjin (CN); Yu-Ren PENG, Tianjin (CN); Duxiang WANG, Tianjin (CN)

(21) Appl. No.: 18/455,975

(22) Filed: Aug. 25, 2023

Related U.S. Application Data
(63) Continuation-in-part of application No. PCT/CN2021/099307, filed on Jun. 10, 2021.

(51) Int. Cl. H01L 33/46; H01L 33/00

(52) U.S. Cl. CPC H01L 33/46; H01L 33/0062; H01L 33/40

(57) ABSTRACT

A light-emitting device includes: a semiconductor epitaxial stack that has a first surface and a second surface, and includes a first semiconductor layer, an active layer, and a second semiconductor layer sequentially stacked on one another in a direction from the second surface to the first surface; a light-transmissive dielectric layer that is disposed on the second surface and that has through holes; an ohmic contact layer that is formed in the through holes and that is in contact with the first semiconductor layer; an adhesion layer that is disposed on the light-transmissive dielectric layer opposite to the semiconductor epitaxial stack; a metal reflection layer that is disposed on the adhesion layer opposite to the semiconductor epitaxial stack; and a diffusion barrier layer that is disposed between the ohmic contact layer and the adhesion layer. A light-emitting apparatus and a method for manufacturing the light-emitting device are also provided.

### CROSS-REFERENCE TO RELATED APPLICATION

This application is a bypass continuation-in-part (CIP) of International Application No. PCT/CN2021/099307, filed on Jun. 10, 2021, which is incorporated herein by reference in its entirety.

### FIELD

The disclosure relates to a semiconductor optoelectronic device, and more particularly to a light-emitting device.

### BACKGROUND

A conventional light-emitting device may be a horizontal type light-emitting device or a vertical type light-emitting device. By transferring a semiconductor epitaxial stack grown on a growth substrate to a supporting substrate such as one made of silicon, silicon carbide or metal, and by removing the growth substrate, the vertical type light-emitting device may effectively improve light absorption, current crowding, and poor heat dissipation as compared to the horizontal type light-emitting device. The transfer of the semiconductor epitaxial stack to the supporting substrate is generally achieved by a bonding process, where bonding is done mainly by metal-metal high temperature and high pressure bonding, i.e., a metal bonding layer is formed between a side of the semiconductor epitaxial stack and the supporting substrate. The other side of the semiconductor epitaxial stack is a light-emitting surface where an electrode is disposed to provide injection or outflow of current, and the supporting substrate is used for the outflow or inflow of the current, thereby forming the light-emitting device having current passing vertically through the semiconductor epitaxial stack.

To improve light-emitting efficiency, a metal reflection layer and a light-transmissive dielectric layer are usually provided on one side of the metal bonding layer, and cooperatively form an ODR reflective structure which reflects light from the metal bonding layer to the light-emitting surface so as to improve the light-emitting efficiency. The light-transmissive dielectric layer has a plurality of through holes and an ohmic contact layer is formed in the through holes. An adhesion layer is disposed between the light-transmissive dielectric layer and the metal reflection layer to improve adhesion between the light-transmissive dielectric layer and the metal reflection layer.

Due to diffusion of materials between the ohmic contact layer and the adhesion layer, ohmic contact between the ohmic contact layer and the semiconductor epitaxial stack is adversely affected, thereby causing a problem of high voltage in the light-emitting device.

### SUMMARY

Therefore, an object of the disclosure is to provide a light-emitting device that can alleviate at least one of the drawbacks of the prior art.

According to one aspect of the disclosure, a light-emitting device includes a semiconductor epitaxial stack, a light-transmissive dielectric layer, an ohmic contact layer, an adhesion layer, a metal reflection layer, and a diffusion barrier layer. The semiconductor epitaxial stack has a first surface and a second surface opposite to the first surface, and includes a first semiconductor layer, an active layer, and a second semiconductor layer sequentially stacked on one another in such order in a direction from the second surface to the first surface. The first surface is a light-exiting surface. The light-transmissive dielectric layer is disposed on the second surface of the semiconductor epitaxial stack and has a plurality of through holes. The ohmic contact layer is formed in the through holes of the light-transmissive dielectric layer and is in contact with the first semiconductor layer. The adhesion layer is disposed on the light-transmissive dielectric layer opposite to the semiconductor epitaxial stack. The metal reflection layer is disposed on the adhesion layer opposite to the semiconductor epitaxial stack. The diffusion barrier layer is disposed between the ohmic contact layer and the adhesion layer.

According to another aspect of the disclosure, a light-emitting apparatus includes the aforesaid light-emitting device.

According to yet another aspect of the disclosure, a method for manufacturing a light-emitting device includes steps of:
providing a semiconductor epitaxial stack that has a first surface and a second surface opposite to the first surface, and that includes a first semiconductor layer, an active layer, and a second semiconductor layer sequentially stacked on one another in such order in a direction from the second surface to the first surface, the first surface being a light-exiting surface;
forming a light-transmissive dielectric layer on the second surface of the semiconductor epitaxial stack, and forming a plurality of through holes in the light-transmissive dielectric layer;
forming an ohmic contact layer in the through holes of the light-transmissive dielectric layer;
forming a diffusion barrier layer on the ohmic contact layer;
forming an adhesion layer on the light-transmissive dielectric layer opposite to the semiconductor epitaxial stack; and
forming a metal reflection layer on the adhesion layer opposite to the semiconductor epitaxial stack.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional schematic view illustrating a first embodiment of a light-emitting device according to the disclosure.

FIG. 2 is a top schematic view of the first embodiment.

FIG. 3 is a cross-sectional schematic view illustrating an embodiment of a light-emitting device according to the disclosure.

FIGS. 4 to 9 are schematic views illustrating a method for manufacturing an embodiment of a light-emitting device according to this disclosure

FIG. 10 is a cross-sectional schematic view illustrating an embodiment of a light-emitting device according to the disclosure.

FIG. 11 is a cross-sectional schematic view illustrating an embodiment of a light-emitting device according to the disclosure.

FIG. 12 is a cross-sectional schematic view illustrating an embodiment of a light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

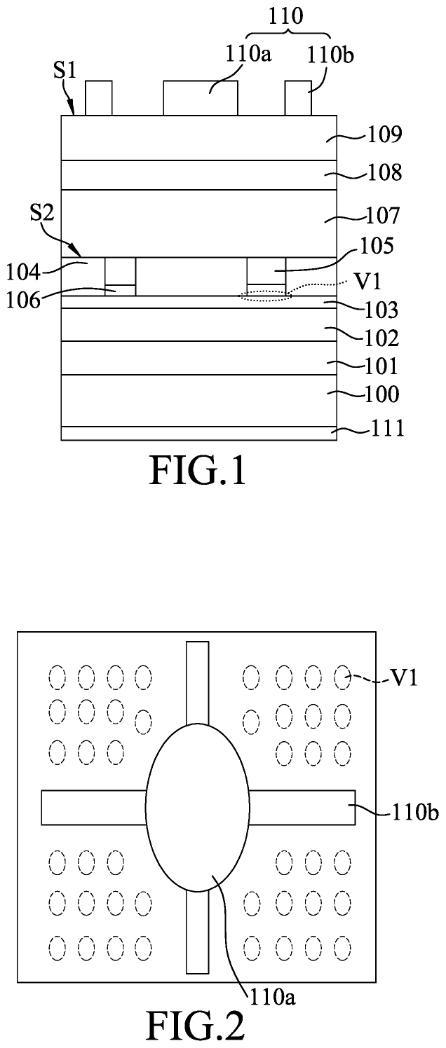

Referring to FIG. 1, a first embodiment of a light-emitting device according to the disclosure includes a supporting substrate 100, a metal bonding layer 101, a metal reflection layer 102, an adhesion layer 103, a light-transmissive dielectric layer 104, an ohmic contact layer 105, a diffusion barrier layer 106, a first semiconductor layer 107, an active layer 108, a second semiconductor layer 109, a first electrode 110, and a second electrode 111 sequentially disposed in such order in a stacking direction. A detailed description of each of the layers is provided below.

The supporting substrate 100 may be a conductive substrate and may be made of silicon, silicon carbide, or metal. Examples of the metal include copper, tungsten, molybdenum, etc. In some embodiments, the supporting substrate 100 has a thickness no smaller than 50 μm so as to have sufficient mechanical strength to support a semiconductor epitaxial stack which includes the first semiconductor layer 107, the active layer 108, and the second semiconductor layer 109. In addition, to facilitate further mechanical processing of the supporting substrate 100 after bonding the supporting substrate 100 to the semiconductor epitaxial stack, the supporting substrate 100 may have a thickness that is no greater than 300 μm. In this embodiment, the supporting substrate 100 is a silicon substrate.

The metal bonding layer 101 serves to bond a side of the semiconductor epitaxial stack to the supporting substrate 100, and may be made of gold, tin, titanium, nickel, platinum, or combinations thereof. The metal bonding layer 101 may be a single-layered structure or a multi-layered structure.

The metal reflection layer 102 is disposed on the metal bonding layer 101 and is closer to the semiconductor epitaxial stack than the metal boning layer 101. The metal reflection layer 102 has a reflectivity no smaller than 70%, and may be made of Ag, Ni, Al, Rh, Pd, Ir, Ru, Mg, Zn, Pt, Au, Hf, or combinations thereof. In this embodiment, the metal reflection layer 102 is made of gold. The metal reflection layer 102 may reflect light radiated by the semiconductor epitaxial stack toward the supporting substrate 100 back to the semiconductor epitaxial stack, and then radiate the light out of a first surface (S1) i.e., a light-exiting surface. The first surface (S1), i.e., the light-exiting surface, is a surface of the second semiconductor layer 109 away from the active layer 108.

The light-transmissive dielectric layer 104 is disposed between the first semiconductor layer 107 and the adhesion layer 103 (i.e., disposed on the first semiconductor layer 107 opposite to the active layer 108), and is made of a high resistance insulating material, such as fluoride, oxide, nitride, or combinations thereof. In some embodiments, the high resistance insulating material may be ZnO, SiO₂, SiOₓ/TiOₓ, SiOₓN_{y}, Si₃N₄, Al₂O₃, and TiOₓ, magnesium fluoride (e.g., MgF₂), gallium fluoride (e.g., GaF₃) or combinations thereof. The light-transmissive dielectric layer 104 is also used to reflect the light radiated from the active layer 108 back inside to the semiconductor epitaxial stack or to a sidewall of the semiconductor epitaxial stack. In certain embodiments, light-transmissive dielectric layer 104 is made of a low refractive index material (e.g., silicon oxide) for increasing possibility of reflection when light radiation penetrates through the semiconductor epitaxial stack to a surface of the light-transmissive dielectric layer 104. In some embodiments, the refractive index is no greater than 1.5, and the light-transmissive dielectric layer 104 has a thickness no smaller than 100 nm, such as ranging from 100 nm to 500 nm. In other embodiments, the thickness of the light-transmissive dielectric layer 104 ranges from 100 nm to 400 nm or from 150 nm to 400 nm. The light-transmissive dielectric layer 104 has a transmittance no smaller than 70%. In some embodiments, the transmittance of the light-transmissive dielectric layer 104 is no smaller than 80% or no smaller than 90%.

The light-transmissive dielectric layer 104 may have a single-layered structure made of the aforesaid high resistance insulating material, or a multi-layered structure. Multiple layers of the multi-layered structure may each be made of different materials, or may be made by alternately stacking two of the abovementioned high resistance insulating materials having different refractive indices. In certain embodiments, the light-transmissive dielectric layer 104 has an optical thickness that is an integer multiple of one-quarter of a light-emitting wavelength. The light-transmissive dielectric layer 104 has a plurality of through holes (V1) as shown in FIG. 2. A cross-section in a horizontal direction of each of the through holes (V1) perpendicular to the stacking direction may have a circular shape, an elliptical shape, or a polygonal shape, and a diameter of each of the through holes (V1) in the horizontal direction may range from 2 μm to 10 μm.

The ohmic contact layer 105 may be disposed in the through holes (V1) and between the metal reflection layer 102 and the light-transmissive dielectric layer 104. The ohmic contact layer 105 forms the ohmic contact with the first semiconductor layer 107, so as to uniformly deliver current from the metal reflection layer 102 and the metal bonding layer 101 to the semiconductor epitaxial stack. That is to say, the ohmic contact layer 105 fills the plurality of through holes and only contacts parts of the first semiconductor layer 107, but not an entire surface of the first semiconductor layer 107. The ohmic contact layer 105 is made of a light-transmissive conductive metal, which may be a metal alloy that includes at least one of Au, Ag, or Al, and at least one of Zn, Be, Ge, or Ni. Examples of the metal alloy includes gold-zinc, gold-germanium, gold-germanium-nickel, or gold-beryllium. The ohmic contact layer 105 may have a single-layered or multi-layered structure. In this embodiment, the ohmic contact layer 105 is made of gold-zinc. The thickness of the light-transmissive dielectric layer 104 is greater than that of the ohmic contact layer 105.

The metal reflection layer 102 and the light-transmissive dielectric layer 104 form an ODR reflective structure to reflect the light radiated by the semiconductor epitaxial stack toward the supporting substrate 100 back to the semiconductor epitaxial stack, and then radiate the light out of the light-exiting surface to improve the light-emitting efficiency.

The adhesion layer 103 is disposed on the light-transmissive dielectric layer 104 opposite to the semiconductor epitaxial stack. In other words, the adhesion layer 103 is disposed between the light-transmissive dielectric layer 104 and the metal reflection layer 102, and is made of a transmissive conductive material, such as IZO or ITO, etc, or a material (e.g., gold or silver) that provides good adhesion between the light-transmissive dielectric layer 104 and the metal reflection layer 102.

In certain embodiments, the adhesion layer 103 has a thickness that is no greater than one-fifth of the thickness of the light-transmissive dielectric layer 104. In certain embodiments, the thickness of the adhesion layer 103 ranges from 1 nm to 10 nm. If the thickness of the adhesion layer 103 is greater than this range, reflectivity of the light-transmissive dielectric layer 104 may be adversely affected, thereby resulting in severe light absorption. On the other hand, if the thickness of the adhesion layer 103 is smaller than this range, poor adhesion may be resulted. Light transmission of the adhesion layer 103 being made of IZO or ITO is typically lower than that of the light-transmissive dielectric layer 104. The adhesion layer 103 having the thickness that ranges from 1 nm to 10 nm may be a continuous layer or, in some embodiments, a discontinuous layer. The ohmic contact layer 105 and the adhesion layer 103 may include same metal atoms.

A direct contact between the ohmic contact layer 105 and the adhesion layer 103 may result in metal diffusion. For example, when the ohmic contact layer 105 is made of AuZn, and the adhesive layer 103 is made of IZO or ITO, Zn in the ohmic contact layer 105 may diffuse into the adhesion layer 103, thereby affecting the ohmic contact between the ohmic contact layer 105 and the first semiconductor layer 107 and voltage of the light-emitting device may increase.

To prevent the metals in the ohmic contact layer 105 from diffusing into the adhesion layer 103, the light-emitting device in this embodiment includes the diffusion barrier layer 106 that is disposed inside the through holes (V1) and between the ohmic contact layer 105 and the adhesion layer 103. The diffusion barrier layer 106 also includes metal atoms, and the metal atoms of the diffusion barrier layer 106 have an atomic mobility lower than that of the metal atoms of the ohmic contact layer 105, so that the diffusion barrier layer 106 may prevent the diffusion of the metal atoms of the ohmic contact layer 105 into the adhesion layer 103.

Referring to FIG. 1, a surface of the diffusion barrier layer 106 and a surface of the light-transmissive dielectric layer 104 away from the semiconductor epitaxial stack are substantially flush, which may ensure surface uniformity of the metal reflection layer 102, thereby enhancing the reflectivity of the metal reflection layer 102 and enhancing the light-emitting efficiency of the light-emitting device.

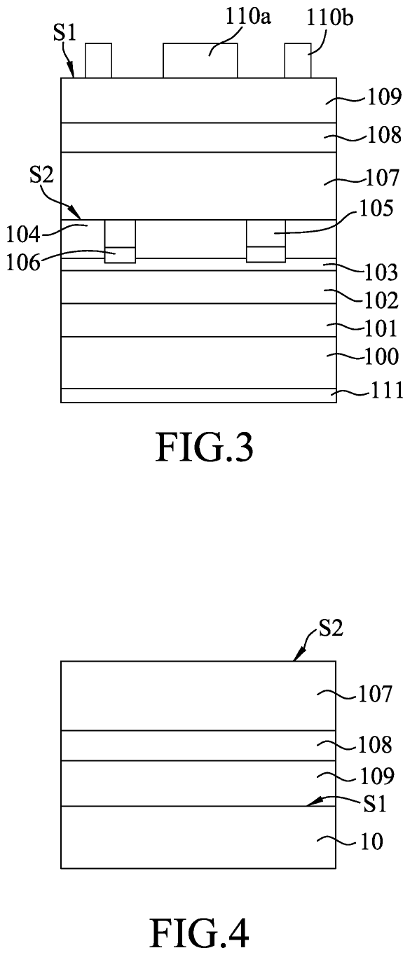

Referring to FIG. 3, in some embodiments, the diffusion barrier layer 106 fills the through holes of the light-transmissive dielectric layer 104 and extends partly outside the through holes. That is to say, the diffusion barrier layer 106 protrudes over a surface of the light-transmissive dielectric layer 104.

The diffusion barrier layer 106 may include Pt, Ti, Ni, Cr, or combinations thereof, and have a thickness ranging from 30 nm to 120 nm. In certain embodiments, the thickness of the diffusion barrier layer 106 ranges from 50 nm to 100 nm.

The semiconductor epitaxial stack has the first surface (S1), a second surface (S2) opposite to the first surface (S1), and the sidewall connecting the first surface (S1) and the second surface (S2). The semiconductor epitaxial stack may be obtained by metal-organic chemical vapor deposition (MOCVD) or other growing methods, and may contain a semiconductor material that generates light, such as ultraviolet light, blue light, green light, yellow light, red light, infrared light, etc. Specifically, the semiconductor material may be a material that generates radiation having a peak wavelength ranging from 200 nm to 950 nm, such as a nitride material. Specifically, the semiconductor epitaxial stack may be a gallium nitride-based epitaxial stack, is doped with aluminum, indium and other materials, and generates radiation having a peak wavelength ranging from 200 nm to 550 nm. The semiconductor epitaxial stack may also be an aluminum gallium indium phosphorus-based epitaxial stack or an aluminum gallium arsenic-based epitaxial stack, and generates radiation having a peak wavelength ranging from 550 nm to 950 nm.

The semiconductor epitaxial stack includes the first semiconductor layer 107, the second semiconductor layer 109, and the active layer 108 disposed between the first semiconductor layer 107 and the second semiconductor layer 109. The first semiconductor layer 107 and the second semiconductor layer 109 may be doped with an n-type dopant and a p-type dopant, respectively, to provide electrons and holes, respectively. The n-type dopant includes Si, Ge, or Sn, and the p-type dopant includes Mg, Zn, Ca, Sr, or Ba. The first semiconductor layer 107 or the second semiconductor layer 109 may include a cladding layer to provide the electrons or the holes, and other layers such as a current spreading layer, a window layer, or an ohmic contact layer, etc. Each of the layers may have a different doping concentration or component content. The active layer 108 is a light-emitting area for the electrons and the holes to recombine. Depending on a wavelength of light emitted by the active layer 108, materials for the active layer 108 may vary. The active layer 108 may be a single quantum well structure or a multiple quantum well structure. By adjusting components of semiconductor materials in the active layer 108, the active layer 108 may emit the light having a pre-determined wavelength. In this embodiment, the semiconductor epitaxial stack is made of AlGaInP-based materials.

The first electrode 110 is disposed on the light-exiting surface (i.e., the first surface (S1)) of the semiconductor epitaxial stack. In some embodiments, the first electrode 110 includes a pad electrode 110a and an extension electrode 110b. The pad electrode 110a is for external wiring during packaging. The pad electrode 110a may be designed to have different shapes, such as a cylindrical shape, a square shape, or other polygonal shapes, depending on actual requirements. The extension electrode 110b may be formed according to a pre-determined pattern, and may have various shapes such as a strip.

The second electrode 111 is disposed on the supporting substrate 100 opposite to the semiconductor epitaxial stack. The supporting substrate 100 in this embodiment is a conductive supporting substrate, and the first electrode 110 and the second electrode 111 are formed on opposite sides of the supporting substrate 100 so as to achieve vertical flow of current through the semiconductor epitaxial stack and to provide uniform current density.

The first electrode 110 and the second electrode 111 may be made of metallic materials. The pad electrode 110a and the extension electrode 110b of the first electrode 110 may further include a metallic material that provides good ohmic contact with the semiconductor epitaxial stack.

A method for manufacturing the light-emitting device of the first embodiment is provided below.

Referring to FIG. 4, the semiconductor epitaxial stack is provided. The semiconductor epitaxial stack has the first surface (S1) and the second surface (S2) opposite to the first surface (S1), and includes the first semiconductor layer 107, the active layer 108, and the second semiconductor layer 109 sequentially stacked on one another in such order in the direction from the second surface (S2) to the first surface (S1). The first surface (S1) is the light-exiting surface.

Specifically, a growth substrate 10 is first provided and may be made of GaAs. By using an epitaxy process, such as MOCVD, the semiconductor epitaxial stack is grown on the growth substrate 10. In this embodiment, the first semiconductor layer 107 is a p-type doped semiconductor layer, and the semiconductor epitaxial stack is made of an AlGaInP-based material. The active layer 108 emits light having a wavelength of red light or infrared light.

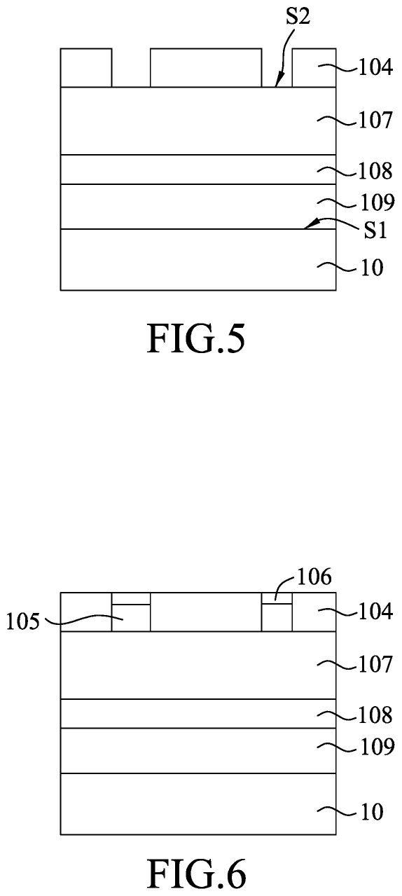

Referring to FIG. 5, the light-transmissive dielectric layer 104 is formed on the first semiconductor layer 107 opposite to the active layer 108. That is to say, the light-transmissive dielectric layer 104 is formed on the second surface (S2) of the semiconductor epitaxial stack. In this embodiment, the light-transmissive dielectric layer 104 is made of SiO₂ or MgF₂. The thickness of the light-transmissive dielectric layer 104 may be no smaller than 100 nm, such as ranging from 100 nm to 500 nm. In other embodiments, the thickness of the light-transmissive dielectric layer 104 ranges from 100 nm to 400 nm or from 150 nm to 400 nm. By masking and etching, the plurality of through holes (V1) are formed in the light-transmissive dielectric layer 104 to expose a portion of the second surface (S2) of the semiconductor epitaxial layer.

Referring to FIG. 6, the ohmic contact layer 105 is formed in the through holes (V1) of the light-transmissive dielectric layer 104. The ohmic contact layer 105 is made of a light-transmissive conductive metal. The light-transmissive conductive metal may be an alloy material such as gold-zinc, gold-germanium, gold-germanium-nickel, or gold-beryllium. In this embodiment, the ohmic contact layer 105 is made of gold-zinc. The thickness of the ohmic contact layer 105 ranges from 80 nm to 400 nm. In some embodiments, the thickness of the ohmic contact layer 105 is no smaller than 150 nm or no smaller than 200 nm. Next, the diffusion barrier layer 106 is formed in the through holes (V1) and on the ohmic contact layer 105. The diffusion barrier layer 106 includes Pt, Ti, Ni, Cr, or combinations thereof, and the thickness of the diffusion barrier layer 106 ranges from 30 nm to 120 nm. The surface of the diffusion barrier layer 106 and the surface of the light-transmissive dielectric layer 104 away from the semiconductor epitaxial stack are substantially flush, which may ensure surface uniformity of the metal reflection layer 102, thereby enhancing the reflectivity of the metal reflection layer 102 and enhancing the light-emitting efficiency of the light-emitting device.

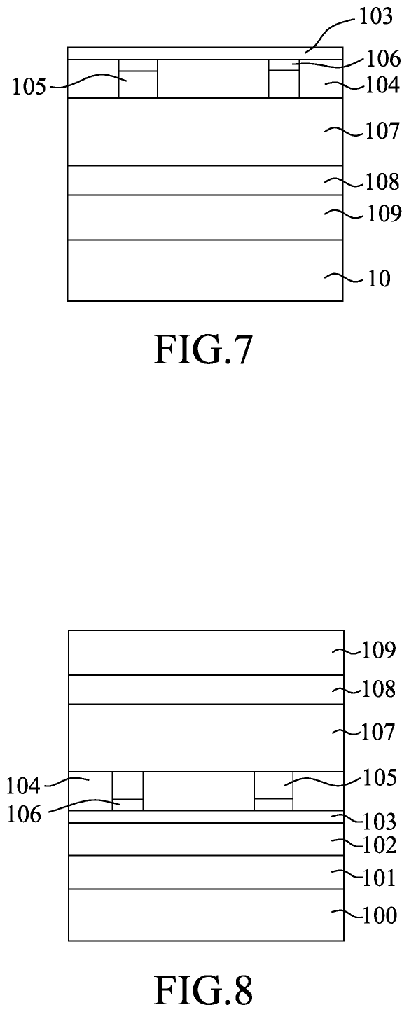

Referring to FIG. 7, the adhesion layer 103 is formed on the light-transmissive dielectric layer 104 opposite to the active layer 108. That is to say, the adhesion layer 103 is formed on the light-transmissive dielectric layer 104 opposite to the semiconductor epitaxial stack. The adhesion layer 103 is made of IZO or ITO. In this embodiment, the adhesion layer 103 is made of IZO. The thickness of the adhesion layer 103 may be no greater than 10 nm, e.g., from 1 nm to 10 nm.

Referring to FIG. 8, the metal reflection layer 102 is formed on the adhesion layer 103 opposite to the semiconductor epitaxial stack. In certain embodiments, the metal reflection layer 102 is made of gold or silver. In this embodiment, the metal reflection layer 102 is made of gold. The metal bonding layer 101 is disposed on the metal reflection layer 102 opposite to the adhesion layer 103, and bonds with the supporting substrate 100 via a bonding technique. Next, the growth substrate 10 is removed by wet etching, thereby obtaining a structure as shown in FIG. 8.

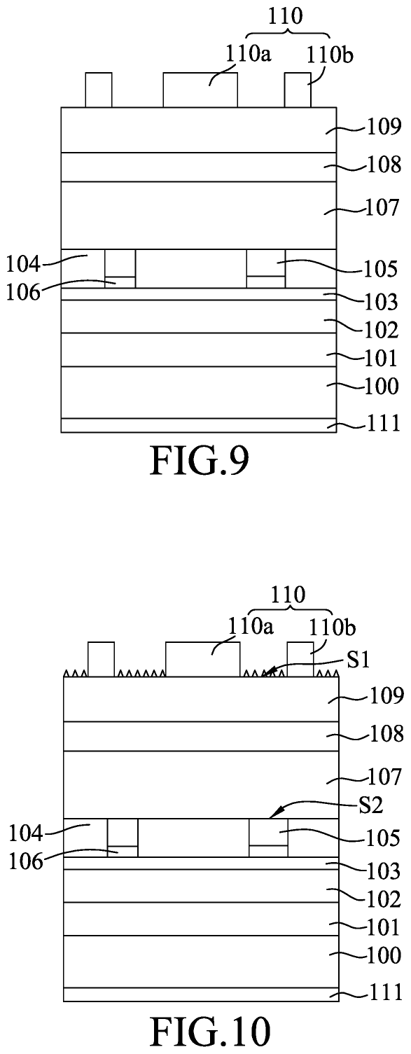

Next, referring to FIG. 9, the first electrode 110 is formed on the second semiconductor layer 109. The first electrode 110 includes the pad electrode 110a for wiring and the extension electrode 110b. The pad electrode 110a and the extension electrode 110b serve to provide wiring positions and horizontal current spreading, respectively.

Finally, the second electrode 111 is disposed on the supporting substrate 100 opposite to the metal bonding layer 101, and the light-emitting device as shown in FIG. 1 is thus obtained.

By disposing the diffusion barrier layer 106 between the ohmic contact layer 105 and the adhesion layer 103, the metals in the ohmic contact layer 105 may be prevented from diffusing into the adhesion layer 103, thereby resolving a problem of high voltage in the light emitting device caused by an inferior ohmic contact between the ohmic contact layer 105 and the semiconductor epitaxial stack. In addition, by disposing the ohmic contact layer 105 and the diffusion barrier layer 106 in the through holes (V1) of the light-transmissive dielectric layer 104 and by making the surface of the diffusion barrier layer 106 flush with the surface of the light-transmissive dielectric layer 104, the surface uniformity of the metal reflection layer 102 may be ensured, thereby improving the reflectivity of the light-emitting device and the light-emitting efficiency of the light-emitting device. At the same time, such configuration may alleviate generation of holes in the metal bonding layer 101 when the semiconductor epitaxial stack is bonded to the supporting substrate 100, thereby improving yield of the light-emitting device.

Compared to the first embodiment as shown in FIG. 1, to further improve the light-emitting efficiency of the light emitted from the active layer 108, the first surface (S1) of the semiconductor epitaxial stack may be roughened as shown in FIG. 10.

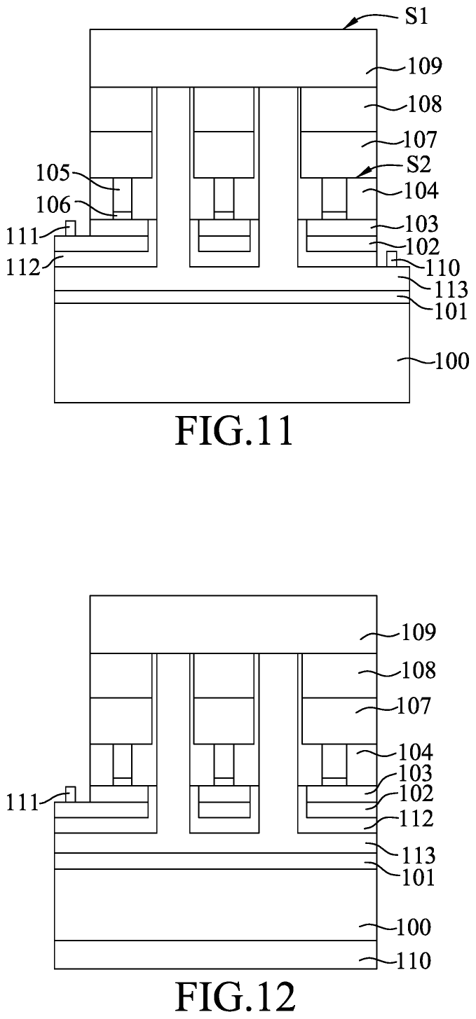

As a modification on the structure shown in FIG. 1, referring to FIG. 11, the first electrode 110 and the second electrode 111 are located on a same side of the supporting substrate 100.

Specifically as shown in FIG. 11, the first surface (S1) of the semiconductor epitaxial stack is the light-exiting surface, and the second surface (S2) of the semiconductor epitaxial stack is a surface of the first semiconductor layer 107. The semiconductor epitaxial stack has a plurality of concave portions that penetrate from the second surface (S2) of the semiconductor epitaxial stack through the active layer 108 to a surface of the second semiconductor layer 109 opposite to the first surface (S1) to expose the surface of the second semiconductor layer 109. A width in the horizontal direction of each of the concave portions is no smaller than 1 μm, and the concave portions occupies 1% to 20% of area of the second surface (S2) of the semiconductor epitaxial stack.

The light-transmissive dielectric layer 104 is formed at least on the second surface (S2) of the semiconductor epitaxial stack. The light-transmissive dielectric layer 104 may also extend to cover sidewall surfaces of the concave portions. The light-transmissive dielectric layer 104 has the through holes that exposes the second surface (S2) of the semiconductor epitaxial stack. The ohmic contact layer 105 fills the through holes of the light-transmissive dielectric layer 104 and is in direct contact with the second surface (S2) of the semiconductor epitaxial stack. The diffusion barrier layer 106 is disposed between the adhesion layer 103 and the ohmic contact layer 105, which may prevent the metals in the ohmic contact layer 105 from diffusing into the adhesion layer 103, thereby solving the problem of high voltage in the light-emitting device caused by the inferior ohmic contact between the ohmic contact layer 105 and the semiconductor epitaxial stack. The adhesive layer 103 is formed on the light-transmissive dielectric layer 104 opposite to the semiconductor epitaxial stack. The metal reflection layer 102 is formed on the adhesive layer 103 opposite to the semiconductor epitaxial stack. The light-transmissive dielectric layer 104 does not cover the concave portions. An insulation layer 112 is disposed on the metal reflection layer 102 opposite to the semiconductor epitaxial stack. The insulation layer 112 may be made of oxide, nitride, or fluoride, such as silicon oxide or silicon nitride. In some embodiments, the insulation layer 112 also extends to cover the sidewall surfaces of the concave portions but exposes the surface of the second semiconductor layer 109 that is exposed from the concave portions.

A second metal layer 113 is disposed on the insulation layer 112 opposite to the semiconductor epitaxial stack. The second metal layer 113 fills the concave portions of the semiconductor epitaxial stack to contact the surface of the second semiconductor layer 109 that is exposed from the concave portions.

A portion of a surface of the metal reflection layer 102 opposite to the insulation layer 112 is exposed, and the second electrode 111 is disposed thereon. A portion of a surface of the second metal layer 113 opposite to the supporting substrate 100 is exposed, and the first electrode 110 is disposed thereon. The first electrode 110 and the second electrode 111 are located on the same side of the supporting substrate 100 for purpose of external wiring.

The supporting substrate 100 is disposed on the second metal layer 113 opposite to the insulation layer 112. The supporting substrate 100 may be a conductive substrate or a non-conductive substrate. The metal bonding layer 101 is further disposed between the second metal layer 113 and the supporting substrate 100 for bonding the second metal layer 113 with the supporting substrate 100.

As an alternative to the embodiment shown in FIG. 11, referring to FIG. 12, the supporting substrate 100 is a conductive substrate, the first electrode 110 is disposed on a back side of the supporting substrate 100 opposite to the semiconductor epitaxial stack for external electrical connection.

The present disclosure also provide a light-emitting apparatus that includes one of the aforesaid embodiments of the light-emitting device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial stack that has a first surface (S1) and a second surface (S2) opposite to said first surface (S1), and that includes a first semiconductor layer (107), an active layer (108), and a second semiconductor layer (109) sequentially stacked on one another in such order in a direction from said second surface (S2) to said first surface (S1), said first surface (S1) being a light-exiting surface;
a light-transmissive dielectric layer (104) that is disposed on said second surface (S2) of said semiconductor epitaxial stack, and that has a plurality of through holes;
an ohmic contact layer (105) that is formed in said through holes of said light-transmissive dielectric layer (104), and that is in contact with said first semiconductor layer (107);
an adhesion layer (103) that is disposed on said light-transmissive dielectric layer (104) opposite to said semiconductor epitaxial stack;
a metal reflection layer (102) that is disposed on said adhesion layer (103) opposite to said semiconductor epitaxial stack; and
a diffusion barrier layer (106) that is disposed between said ohmic contact layer (105) and said adhesion layer (103).

2. The light-emitting device as claimed in claim 1, wherein said diffusion barrier layer (106) is disposed inside said through holes of said light-transmissive dielectric layer (104).

3. The light-emitting device as claimed in claim 1, wherein said diffusion barrier layer (106) fills said through holes of said light-transmissive dielectric layer (104) and extends partly outside said through holes.

4. The light-emitting device as claimed in claim 1, wherein said ohmic contact layer (105) and said adhesion layer (103) include same metal atoms.

5. The light-emitting device as claimed in claim 1, wherein each of said diffusion barrier layer (106) and said ohmic contact layer (105) includes metal atoms, said metal atoms of said diffusion barrier layer (106) having an atomic mobility lower than that of said metal atoms of said ohmic contact layer (105).

6. The light-emitting device as claimed in claim 1, wherein said diffusion barrier layer (106) includes Pt, Ti, Ni, Cr, or combinations thereof.

7. The light-emitting device as claimed in claim 1, wherein said light-transmissive dielectric layer (104) has a thickness greater than that of said ohmic contact layer (105).

8. The light-emitting device as claimed in claim 1, wherein said diffusion barrier layer (106) has a thickness ranging from 30 nm to 120 nm.

9. The light-emitting device as claimed in claim 1, wherein said ohmic contact layer (105) is made of a metal alloy that includes at least one of Au, Ag, or Al, and at least one of Zn, Be, Ge, or Ni.

10. The light-emitting device as claimed in claim 1, wherein said light-transmissive dielectric layer (104) has a thickness ranging from 100 nm to 500 nm.

11. The light-emitting device as claimed in claim 1, wherein said adhesion layer (103) is disposed between said light-transmissive dielectric layer (104) and said metal reflection layer (102) and is made of a light-transmissive material.

12. The light-emitting device as claimed in claim 1, wherein said adhesion layer (103) is made of one of IZO and ITO.

13. The light-emitting device as claimed in claim 1, wherein said adhesion layer (103) has a thickness ranging from 1 nm to 10 nm.

14. The light-emitting device as claimed in claim 1, wherein said light-transmissive dielectric layer (104) has one of a single-layered structure and a multi-layered structure, and is made of one of nitride, oxide, fluoride, and combinations thereof.

15. The light-emitting device as claimed in claim 1, wherein said metal reflection layer (102) has a reflectivity no smaller than 70%.

16. The light-emitting device as claimed in claim 1, wherein said metal reflection layer (102) is made of one of Ag, Ni, Al, Rh, Pd, Ir, Ru, Mg, Zn, Pt, Au, Hf, and combinations thereof.

17. The light-emitting device as claimed in claim 1, wherein said light-emitting device emits light having a wavelength of one of red light and infrared light.

18. The light-emitting device as claimed in claim 1, wherein said semiconductor epitaxial stack further has a plurality of concave portions that penetrate from said second surface (S2) of said semiconductor epitaxial stack through said active layer (108) to a surface of said second semiconductor layer (109) opposite to said first surface (S1).

19. A light-emitting apparatus, comprising the light-emitting device as claimed in claim 1.

20. A method for manufacturing a light-emitting device, comprising steps of:
providing a semiconductor epitaxial stack that has a first surface (S1) and a second surface (S2) opposite to said first surface (S1), and that includes a first semiconductor layer (107), an active layer (108), and a second semiconductor layer (109) sequentially stacked on one another in such order in a direction from said second surface (S2) to said first surface (S1), said first surface (S1) being a light-exiting surface;
forming a light-transmissive dielectric layer (104) on said second surface (S2) of said semiconductor epitaxial stack, and forming a plurality of through holes in the light-transmissive dielectric layer (104);
forming a ohmic contact layer (105) in said through holes of said light-transmissive dielectric layer (104);
forming a diffusion barrier layer (106) on said ohmic contact layer (105);
forming an adhesion layer (103) on said light-transmissive dielectric layer (104) opposite to said semiconductor epitaxial stack; and
forming a metal reflection layer (102) on said adhesion layer (103) opposite to said semiconductor epitaxial stack.
